(19) United States
(12) Patent Application Publication
(10) Pub. No.: US 2026/0093150 A1
(43) Pub. Date: Apr. 2, 2026

(54) DISPLAY PANEL, METHOD FOR PREPARING DISPLAY PANEL, AND DISPLAY DEVICE

(71) Applicant: Guangzhou China Star Optoelectronics Semiconductor Display Technology Co., Ltd., Guangzhou (CN)

(72) Inventor: Jia TANG, Guangzhou (CN)

(73) Assignee: Guangzhou China Star Optoelectronics Semiconductor Display Technology Co., Ltd., Guangzhou (CN)

(21) Appl. No.: 19/023,689

(22) Filed: Jan. 16, 2025

(30) Foreign Application Priority Data
Sep. 30, 2024 (CN) 202411392233.0

(51) Int. Cl. G02F 1/1362; H10D 86/40; H10D 86/60

(52) U.S. Cl. CPC G02F 1/136295; G02F 1/136209; H10D 86/443; H10D 86/60

(57) ABSTRACT

Embodiments of this application provide a display panel, a method for preparing display panel, and a display device. The display panel includes a substrate; a first conductive layer disposed on the substrate and including a data line and a light-shielding portion; a semiconductor layer disposed on a side of the first conductive layer away from the substrate and including an active portion and a functional electrode spaced apart, the active portion including a channel portion as well as first and second contact portions connected to either side of the channel portion; and a second conductive layer disposed on a side of the semiconductor layer away from the first conductive layer and including first and second electrode members. The first electrode member is connected to the first contact portion and the data line, and a part of the second electrode member is connected to the second contact portion.

### CROSS-REFERENCE TO RELATED APPLICATION

This application claims priority to and the benefit of Chinese Patent Application No. 202411392233.0 filed on Sep. 30, 2024, the disclosure of which is incorporated herein by reference in its entirety.

### TECHNICAL FIELD

The present disclosure relates to display technologies, and in particular, to a display panel, a method for preparing the display panel, and a display device.

### BACKGROUND

A Thin Film Transistor (TFT) array substrate is an important component of a display device and can be formed on a glass substrate or a flexible substrate. The thin film transistor array substrate is typically used as a switching and driving device in the display device such as a Liquid Crystal Display (LCD) device and an Organic Light Emitting Display (OLED) device.

However, in a manufacturing process of the thin-film transistor array substrate, several photomasks for photolithography processes are required to form multiple layers of the thin-film transistor array substrate. Specifically, referring to FIG. 1, the array substrate includes a data line layer 1 disposed on a substrate, a buffer layer 2 disposed on the substrate and covering the data line layer 1, a semiconductor layer 3 disposed on the buffer layer 2, a gate insulating layer 4a and a gate layer 4b disposed on the semiconductor layer 3, a first inorganic insulating layer 5 disposed on the buffer layer 2 and covering the semiconductor layer 3 and the gate layer 4, an organic insulating layer 6 disposed on the first inorganic insulating layer 5, a common electrode layer 7 disposed on the organic insulating layer 6, a second inorganic insulating layer 8 disposed on the organic insulating layer 6 and covering the common electrode layer 7, and a pixel electrode layer 9 disposed on the second inorganic insulating layer 8. Specifically, one photomask is required to form the data line layer 1, one photomask is required to form via holes in the buffer layer 2, one photomask is required to form the semiconductor layer 3, one photomask is required to form the gate layer 4 and the gate insulating layer 4a, one photomask is required to form via holes in the organic insulating layer 6, one photomask is required to form via holes in the first inorganic insulating layer 5 and the second inorganic insulating layer 8, one photomask is required to form the common electrode layer 7, and one photomask is required to form the pixel electrode layer 9. That is, eight photomask processes are required to form the structure of the array substrate shown in FIG. 1, resulting in higher production costs, more complex processes, and higher photomask costs, thereby increasing costs, time and complexity of the manufacturing process of the thin-film transistor array substrate with increasing the number of photomasks.

### SUMMARY

According to one or more embodiments of the present disclosure, a display panel is provided, including: a substrate; a first conductive layer disposed on the substrate and including a data line and a light-shielding portion; a semiconductor layer disposed on a side of the first conductive layer away from the substrate and including an active portion and a functional electrode spaced apart, the active portion including a channel portion as well as a first contact portion and a second contact portion connected to either side of the channel portion; and a second conductive layer disposed on a side of the semiconductor layer away from the first conductive layer. The second conductive layer includes a first electrode member and a second electrode member, the first electrode member is connected to the first contact portion and the data line, a part of the second electrode member is connected to the second contact portion, and another part of the second electrode member is located on a side of the functional electrode away from the substrate.

According to one or more embodiments of the present disclosure, a method for preparing a display panel is provided. The method includes the following steps:
forming a first conductive layer on a substrate, with the first conductive layer including a data line and a light-shielding portion;
forming a semiconductor layer on a side of the first conductive layer away from the substrate, with the semiconductor layer including an active portion and a functional electrode spaced apart, wherein the active portion includes a channel portion, and a first contact portion and a second contact portion connected to either side of the channel portion; and
forming a second conductive layer on a side of the semiconductor layer away from the first conductive layer, the second conductive layer including a first electrode member and a second electrode member, wherein the first electrode member is connected to the first contact portion and the data line, a part of the second electrode member is connected to the second contact portion, and another part of the second electrode member is located on a side of the functional electrode away from the substrate.

According to one or more embodiments of the present disclosure, a display device which includes the display panel as mentioned above is provided.

### BRIEF DESCRIPTION OF THE DRAWINGS

In order to more clearly illustrate the technical solutions in the embodiments of this disclosure, the accompanying drawings to be used in the description of the embodiments will be briefly introduced below. It is to be noted that the accompanying drawings in the following description are merely illustrative of some embodiments of this disclosure, and that other accompanying drawings may be made by the skilled person in the art without involving any inventive effort.

In order to fully understand the present disclosure and its advantageous effects, the following description will be made in conjunction with the accompanying drawings, wherein identical reference numerals indicate identical parts in the subsequent description.

FIG. 1 is a schematic diagram of a structure of a display panel in prior art.

FIG. 2 is a schematic diagram of a first structure of a display panel according to one or more embodiments of this disclosure.

FIG. 3 is a schematic diagram of a second structure of a display panel according to one or more embodiments of this disclosure.

FIG. 4 is a schematic diagram of a third structure of a display panel according to one or more embodiments of this disclosure.

FIG. 5 is a schematic diagram of a fourth structure of a display panel according to one or more embodiments of this disclosure.

FIG. 6 is a flowchart of a method for preparing a display panel according to one or more embodiments of this disclosure.

FIGS. 7 to 12 are schematic diagrams illustrating a manufacturing process for a display panel according to one or more embodiments of this disclosure.

FIGS. 13 to 15 are schematic diagrams illustrating another manufacturing process of a display panel according to one or more embodiments of this disclosure.

### DESCRIPTION OF REFERENCE NUMERALS IN DRAWINGS

10, Substrate; 101, First Opening; 102, Second Opening; 103, Third Opening; 104, Fourth Opening; 1011, First Intermediate Opening; 1021, Second Intermediate Opening; 1031, Third Intermediate Opening; 1041, Fourth Intermediate Opening; 20, First Conductive Layer; 21, Data Line; 22, Light-shielding Portion; 30, Semiconductor Layer; 31, Active Portion; 311, Channel Portion; 312, First Contact Portion; 313, Second Contact Portion; 32; Functional Electrode; 300, Semiconductor Material Layer; 40, Second Conductive Layer; 41, First Electrode Member; 42, Second Electrode Member; 421, First Sub-electrode; 422, Second Sub-electrode; 51, Buffer Layer; 511, First Sub-portion; 512, Second Sub-portion; 510, Buffer Material Layer; 52, First Insulating Layer; 53, Second Insulating Layer; 531, Organic Insulating Sublayer; 532, Inorganic Insulating Sublayer; 54, Pixel Defining Layer; 55, Light-emitting Functional Layer; 56, Cathode Layer; 61, Gate Insulating Portion; 62, Gate Electrode; 610, Gate Insulating Material Layer; 620, Gate Material Layer; 70, Photoresist Layer; 71, First Photoresist Block; 72, Second Photoresist Block; 100, Display Panel.

### DETAILED DESCRIPTION

The technical solution in the embodiments of this disclosure will be clearly and completely described with reference to the accompanying drawings. It will be apparent that the described embodiments are only part of the embodiments of this disclosure, and not all of them. Based on the embodiments in this disclosure, all other embodiments obtained by the skilled person in the art without involving any inventive effort are within the scope of this disclosure.

Referring to FIG. 2, one or more embodiments of this disclosure provide a display panel 100, which includes a substrate 10, a first conductive layer 20, a semiconductor layer 30, and a second conductive layer 40.

The first conductive layer 20 is disposed on the substrate 10. The first conductive layer 20 includes a data line 21 and a light-shielding portion 22. The semiconductor layer 30 is disposed on a side of the first conductive layer 20 away from the substrate 10. The semiconductor layer 30 includes an active portion 31 and a functional electrode 32, which are spaced apart. The active portion 31 includes a channel portion 311, a first contact portion 312, and a second contact portion 313, with the first contact portion 312 and the second contact portion 313 being connected to either side of the channel portion 311. The second conductive layer 40 is disposed on a side of the semiconductor layer 30 away from the first conductive layer 20.

Furthermore, the second conductive layer 40 includes a first electrode member 41 and a second electrode member 42. The first electrode member 41 is connected to the first contact portion 312 and the data line 21. A part of the second electrode member 42 is connected to the second contact portion 313, while another part of the second electrode member 42 is located on a side of the functional electrode 32 away from the substrate 10.

In an implementation process, according to one or more embodiments of this disclosure, the functional electrode 32 is formed by using the semiconductor layer 30, and the first electrode member 41 and the second electrode member 42 are made on a same film layer. That is, the first electrode member 41 and the second electrode member 42 are located in the second conductive layer 40. The second electrode member 42 is connected to the second contact portion 313, serving as a source electrode or a drain electrode; additionally, the second electrode member 42 is located on the side of the functional electrode 32 away from the substrate 10, i.e., the second electrode member 42 is arranged opposite to the functional electrode 32. Thus, capacitance can be generated between the functional electrode 32 and the oppositely-arranged second electrode member 42. As a result, in one or more embodiments of this disclosure, the need for an additional photomask to fabricate a capacitor plate can be eliminated, which is conducive to reducing the number of photomasks required in the display panel manufacturing process, lowering the process cost of the display panel, and shortening the process time of the display panel.

Specifically, referring to FIG. 2, the display panel 100 further includes a buffer layer 51, a gate electrode 62, a gate insulating layer 61, a first insulating layer 52, and a second insulating layer 53. The buffer layer 51 is disposed between the first conductive layer 20 and the semiconductor layer 30. The first insulating layer 52 is disposed between the semiconductor layer 30 and the second conductive layer 40. The second insulating layer 53 is disposed between the first insulating layer 52 and the second conductive layer 40. The gate insulating layer 61 is disposed between the semiconductor layer 30 and the first insulating layer 52. The gate electrode 62 is disposed between the gate insulating layer 61 and the first insulating layer 52.

In some embodiments, the first conductive layer 20 includes the data line 21 and the light-shielding portion 22, which are spaced apart. The semiconductor layer 30 includes the active portion 31 and the functional electrode 32, which are spaced apart. The light-shielding portion 22 can be positioned between the active portion 31 and the substrate 10. The active portion 31 includes the channel portion 311, the first contact portion 312, and the second contact portion 313, which are connected to opposite sides of the channel portion 311. Notably, the light-shielding portion 22 is at least positioned between the channel portion 311 and the substrate 10, and an orthographic projection of the channel portion 311 on the substrate 10 lies within a coverage area of an orthographic projection of the light-shielding portion 22 on the substrate 10. This arrangement allows the light-shielding portion 22 to block light from a side close to the substrate 10, thereby reducing the impact of light on the electrical properties of the channel portion 311.

It can be understood that the channel portion 311 is made of semiconductor material, while the first contact portion 312, the second contact portion 313, and the functional electrode 32 can be formed by treating the semiconductor material through a conductorization process.

In some embodiments, the material of the semiconductor layer 30 may include oxide semiconductor materials, specifically metal oxide semiconductors. For instance, the material of the semiconductor layer 30 may include at least one of indium zinc oxides (IZO), gallium indium oxides (IGO), indium gallium zinc oxides (IGZO), indium gallium tin oxides (IGTO), and indium gallium zinc tin oxides (IGZTO).

In some embodiments, the buffer layer 51 includes a first sub-portion 511 and a second sub-portion 512 that are spaced apart. The first sub-portion 511 is disposed on the substrate 10 and covers the light-shielding portion 22, and the first sub-portion 511 is located between the substrate 10 and the active portion 31. Additionally, the first sub-portion 511 is located between the light-shielding portion 22 and the active portion 31, and the second sub-portion 512 is located between the substrate 10 and the functional electrode 32.

It should be noted that the first sub-portion 511 and the second sub-portion 512 of the buffer layer 51 are respectively aligned with the active portion 31 and the functional electrode 32 of the semiconductor layer 30. Thus, in the manufacturing process, the same photomask can be used to pattern the buffer layer 51 and the semiconductor layer 30 to form the first sub-portion 511, the second sub-portion 512, the active portion 31, and the functional electrode 32. Consequently, the pattern of the buffer layer 51 is identical to the pattern of the semiconductor layer 30, i.e., an orthogonal projection of the buffer layer 51 on the substrate 10 coincides with an orthogonal projection of the semiconductor layer 30 on the substrate 10. Thus, in one or more embodiments of this disclosure, the number of photomasks required in the display panel manufacturing process can be effectively reduced, thereby lowering the production cost of the display panel.

In some embodiments, the gate insulating layer 61 is disposed on a surface of the active portion 31 away from the first sub-portion 511. Additionally, the gate insulating layer 61 is disposed on a surface of the channel portion 311 away from the first sub-portion 511. The gate electrode 62 is disposed on a surface of the gate insulating layer 61 away from the active portion 31. Additionally, the gate electrode 62 is disposed on a surface of the gate insulating layer 61 away from the channel portion 311.

In some embodiments, the first insulating layer 52 covers the gate electrode 62, and parts of the substrate 10, the data line 21, the active portion 31, and the functional electrode 32. The second insulating layer 53 is disposed on a side of the first insulating layer 52 away from the substrate 10, and the second conductive layer 40 is disposed on the second insulating layer 53.

The second conductive layer 40 includes the first electrode member 41 and the second electrode member 42, which are spaced apart. The second electrode member 42 includes a first sub-electrode 421 and a second sub-electrode 422, which are connected. The first sub-electrode 421 is located on a side of the functional electrode 32 away from the substrate 10 and is spaced apart from the functional electrode 32.

In some embodiments, the material of the second conductive layer 40 includes indium tin oxides (ITO).

In some embodiments, the display panel 100 has a first opening 101 located on a side of the functional electrode 32 away from the substrate 10. A depth of the first opening 101 is smaller than a combined thickness of the first insulating layer 52 and the second insulating layer 53 on the side of the functional electrode 32 away from the substrate 10. The first sub-electrode 421 is arranged at the bottom of the first opening 101 and is spaced apart from the functional electrode 32. In these embodiments, the first opening 101 is formed in the first insulating layer 52 and/or the second insulating layer 53, the first opening 101 penetrates through a part of film layers of the first insulating layer 52 and the second insulating layer 53, and the first sub-electrode 421 is arranged within the first opening 101, thereby reducing a distance between the functional electrode 32 and the first sub-electrode 421. This arrangement can increase the capacitance of a storage capacitor formed by the functional electrode 32 and the first sub-electrode 421, thereby improving the display effect of the display panel.

In some embodiments, the display panel 100 further has a second opening 102 and a third opening 103. The second opening 102 penetrates through the second insulating layer 53 and the first insulating layer 52, and corresponds to the first contact portion 312. The third opening 103 penetrates through the second insulating layer 53 and the first insulating layer 52, and corresponds to the second contact portion 313. At least a portion of a surface of the first contact portion 312 can be exposed through the second opening 102, and at least a portion of a surface of the second contact portion 313 can be exposed through the third opening 103. The first electrode member 41 extends through the second opening 102 to connect with the first contact portion 312. One end of the second sub-electrode 422 is located on a side of the second insulating layer 53 away from the first insulating layer 52, and the other end of the second sub-electrode 422 extends through the third opening 103 to connect with the second contact portion 313. For example, when the display panel 100 is a Liquid Crystal Display (LCD) panel, the second sub-electrode 422 can serve as a pixel electrode, the functional electrode 32 forms an edge electric field with the second sub-electrode 422 to drive liquid crystal molecules to deflected, and additionally, the functional electrode 32 and the first sub-electrode 421, which are oppositely arranged, can form the storage capacitor. Thus, the display panel 100 provided in these embodiments can be an HFS-type LCD panel.

It should be noted that the second sub-electrode 422 and the first sub-electrode 421 are integrally formed structures. This means that a part of the second electrode member 42 can serve as the pixel electrode and generate the edge electric field with the functional electrode 32, another part of the second electrode member 42 is disposed opposite to the functional electrode 32 to form the storage capacitor, and yet another part of the second electrode member 42 is connected to the second contact portion 313 to serve as a source or drain electrode.

Furthermore, the display panel 100 is provided with a fourth opening 104, which penetrates through the second insulating layer 53 and the first insulating layer 52, and corresponds to the data line 21. A portion of a surface of the data line 21 can be exposed through the fourth opening 104, and the first electrode 41 extends through the fourth opening 104 to connect with the data line 21.

In addition, the first electrode member 41 covers sidewalls of the second opening 102, sidewalls of the fourth opening 104, a portion of a surface of the data line 21 away from the substrate 10, and at least a portion of a surface of the first contact portion 312 away from the substrate 10. The second sub-electrode 422 covers sidewalls of the third opening 103 and at least a portion of a surface of the second contact portion 313 away from the substrate 10.

In some embodiments, the first opening 101 is located on the side of the functional electrode 32 away from the substrate 10, the second opening 102 is located on the side of the first contact portion 312 away from the substrate 10, the third opening 103 is located on the side of the second contact portion 313 away from the substrate 10, and the fourth opening 104 is located on the side of the data line 21 away from the substrate 10. Additionally, since the first conductive layer 20 is closer to the substrate 10 relative to the semiconductor layer 30, a depth of the fourth opening 104 is greater than a depth of the first opening 101, the depth of the fourth opening 104 is greater than a depth of the second opening 102, and the depth of the fourth opening 104 is greater than a depth of the third opening 103. The depths of the first opening 101, the second opening 102, and the third opening 103 may be equal to each other.

In one embodiment of this disclosure, referring to FIG. 2, the second insulating layer 53 includes an organic insulating sublayer 531 positioned between the first insulating layer 52 and the second conductive layer 40, and an inorganic insulating sublayer 532 positioned between the organic insulating sublayer 531 and the second conductive layer 40. The organic insulating sublayer 531 covers the first insulating layer 52, the inorganic insulating sublayer 532 covers the organic insulating sublayer 531, and the second conductive layer 40 is disposed on the inorganic insulating sublayer 532.

In some embodiments, the buffer layer 51, the first insulating layer 52, and the inorganic insulating sublayer 532 each can include inorganic materials, such as silicon nitride or silicon oxide, etc. The organic insulating sublayer 531 can include organic materials, such as polyimide, polycarbonate, or polymethyl methacrylate, etc.

The first opening 101 penetrates through the organic insulating sublayer 531 and the first insulating layer 52. Sidewalls of the first opening 101 are surfaces of the inorganic insulating sublayer 532. The inorganic insulating sublayer 532 is disposed between the first sub-electrode 421 and the functional electrode 32 to separate them. A water vapor barrier performance of the inorganic insulating sublayer 532 is superior to that of the organic insulating sublayer 531. Therefore, making the inorganic insulating sublayer 532 being the sidewalls of the first opening 101 can significantly enhance the water vapor barrier performance of the sidewalls of the first opening 101.

Additionally, there is only the inorganic insulating sublayer 532 between the functional electrode 32 and the first sub-electrode 421. This arrangement can further reduce the distance between the functional electrode 32 and the first sub-electrode 421, thereby effectively increasing the capacitance generated between them.

Furthermore, the second opening 102 penetrates through the inorganic insulating sublayer 532, the organic insulating sublayer 531, and the first insulating layer 52, exposing at least a portion of the surface of the first contact portion 312. The sidewalls of the second opening 102 are the surfaces of the inorganic insulating sublayer 532, the organic insulating sublayer 531, and the first insulating layer 52. The third opening 103 penetrates through the inorganic insulating sublayer 532, the organic insulating sublayer 531, and the first insulating layer 52, exposing at least a portion of the surface of the second contact portion 313. The sidewalls of the third opening 103 are the surfaces of the inorganic insulating sublayer 532, the organic insulating sublayer 531, and the first insulating layer 52. The fourth opening 104 penetrates through the inorganic insulating sublayer 532, the organic insulating sublayer 531, and the first insulating layer 52, exposing a portion of the surface of the data line 21. The sidewalls of the fourth opening 104 are the surfaces of the inorganic insulating sublayer 532, the organic insulating sublayer 531, and the first insulating layer 52.

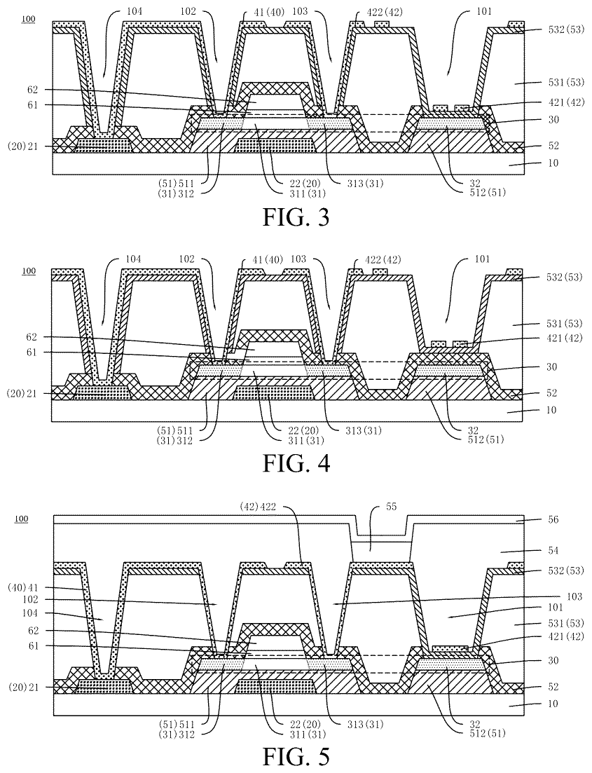

In another embodiment of this disclosure, referring to FIG. 3, which differs from the embodiment shown in FIG. 2 in the following ways: the second opening 102 penetrates through the inorganic insulating sublayer 532, the organic insulating sublayer 531, and the first insulating layer 52, exposing at least a portion of the surface of the first contact portion 312; the sidewalls of the second opening 102 are the surface of the inorganic insulating sublayer 532 and the surface of the first insulating layer 52; the third opening 103 penetrates through the inorganic insulating sublayer 532, the organic insulating sublayer 531, and the first insulating layer 52, exposing at least a portion of the surface of the second contact portion 313; the sidewalls of the third opening 103 are the surfaces of the inorganic insulating sublayer 532 and the first insulating layer 52; the fourth opening 104 penetrates through the inorganic insulating sublayer 532, the organic insulating sublayer 531, and the first insulating layer 52, exposing a portion of the surface of the data line 21; and the sidewalls of the fourth opening 104 are the surfaces of the inorganic insulating sublayer 532 and the first insulating layer 52.

In this context, the sidewalls of the second opening 102, the sidewalls of the third opening 103, and the sidewalls of the fourth opening 104 are all the surfaces of the inorganic insulating sublayer 532 and the first insulating layer 52, which means they are all inorganic material surfaces. Thus, this arrangement can effectively enhance the water vapor barrier performance of the sidewalls of the second opening 102, the third opening 103, and the fourth opening 104, compared to an arrangement in which they are all organic material surfaces.

In yet another embodiment of this disclosure, referring to FIG. 4, a difference between the embodiment depicted in FIG. 3 is that: the first opening 101 penetrates through the organic insulating sublayer 531, with the sidewalls of the first opening 101 being the surface of the inorganic insulating sublayer 532; and the inorganic insulating sublayer 532 and the first insulating layer 52 are disposed between the first sub-electrode 421 and the functional electrode 32 to separate them. The inorganic insulating sublayer 532 has a better water vapor barrier performance compared to the organic insulating sublayer 531. Therefore, making the inorganic insulating sublayer 532 being the sidewalls of the first opening 101 can effectively improve the water vapor barrier performance of the sidewalls of the first opening 101. Additionally, the inorganic insulating sublayer 532 and the first insulating layer 52 are disposed between the functional electrode 32 and the first sub-electrode 421; in other words, two insulating layers are disposed between the functional electrode 32 and the first sub-electrode 421, thereby effectively reducing probabilities of a breakdown and/or a short circuit between the functional electrode 32 and the first sub-electrode 421, and enhancing a stability and lifespan of the display panel.

In another embodiment of this disclosure, referring to FIG. 2, FIG. 3, and FIG. 4, the display panel 100 may also include a liquid crystal layer located on a side of the second conductive layer 40 away from the substrate 10, as well as an opposite substrate located on a side of the liquid crystal layer away from the second conductive layer 40. Additionally, a structure, like a color filter layer, can be arranged on the opposite substrate, which means the display panel 100 can be a liquid crystal display panel.

The second electrode member 42 serves as the pixel electrode, and the second electrode member 42 is electrically connected to the active portion 31, the first electrode member 41, and the data line 21, in order to receive a data signal from the data line 21.

The first sub-electrode 421 of the second electrode member 42 is positioned opposite to the functional electrode 32 to form a storage capacitor. The edge electric field is generated between the second sub-electrode 422 of the second electrode member 42 and the functional electrode 32, which can drive the liquid crystal molecules in the liquid crystal layer to deflect, thereby enabling the display function of the display panel.

In the embodiments of this disclosure, it is noted that the pixel electrode is also used as the source electrode (or drain electrode) and the capacitor plate, which means the pixel electrode, the source electrode (or drain electrode), and the capacitor plate can be formed by using a single photomask. Accordingly, the number of photomasks required in the display panel manufacturing process can be significantly reduced, thereby lowering production costs.

In yet another embodiment of this disclosure, referring to FIG. 5, a difference between the embodiment shown in FIG. 2 is that the display panel 100 provided in this embodiment is an Organic Light Emitting Diode (OLED) display panel.

Specifically, the display panel 100 further includes a pixel defining layer 54, a light-emitting functional layer 55, and a cathode layer 56. The pixel defining layer 54 and light-emitting functional layer 55 are disposed on the side of the second conductive layer 40 away from the substrate 10. The cathode layer 56 is disposed on sides of the pixel defining layer 54 and the light-emitting functional layer 55 away from the second conductive layer 40. The second electrode member 42 may serve as an anode.

The pixel defining layer 54 is disposed on the side of the second conductive layer 40 away from the substrate 10 and fills in the first opening 101, the second opening 102, the third opening 103, and the fourth opening 104. Multiple pixel openings are formed in the pixel defining layer 54, exposing the surface of the second electrode member 42. The light-emitting functional layer 55 is at least disposed within each pixel opening and is located on a surface of the second electrode member 42 away from the inorganic insulating sublayer 532. The cathode layer 56 covers surfaces of the pixel defining layer 54 and the light-emitting functional layer 55 away from the second electrode member 42.

In the embodiments of this disclosure, it can be understood that the anode is also used as the source electrode (or drain electrode) and the capacitor plate, which means the anode, the source electrode (or drain electrode), and the capacitor plate can be formed by using a single photomask. Accordingly, the number of photomasks required in the display panel manufacturing process can be effectively reduced, thereby lowering production costs.

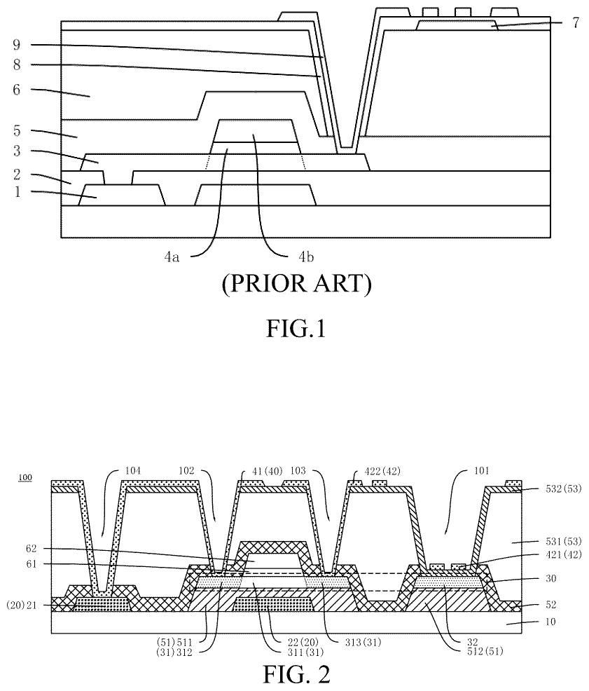

In another embodiment of this disclosure, the second insulating layer 53 may include either an organic insulating sublayer 531 disposed between the first insulating layer 52 and the second conductive layer 40, or an inorganic insulating sublayer 532 disposed between the first insulating layer 52 and the second conductive layer 40. As the display panel 100 in the embodiments of this disclosure reduces preparation of a common electrode layer 7 compared to the prior art shown in FIG. 1, preparation of the organic insulating sublayer 531 or the inorganic insulating sublayer 532 can be accordingly reduced. This reduction can decrease the number of photomasks required in the display panel manufacturing process, thereby lowering production costs, and reducing an overall thickness of the display panel.

In addition, in one or more embodiments of this disclosure, the functional electrode 32 is formed by using the semiconductor layer 30, and the first electrode member 41 and the second electrode member 42 are made in the same film layer, i.e., the second conductive layer 40. The second electrode member 42 is connected to the second contact portion 313, serving as the source or drain electrode; additionally, the second electrode member 42 is located on the side of the functional electrode 32 away from the substrate 10, i.e., the second electrode member 42 is arranged opposite to the functional electrode 32, thereby forming a storage capacitor. As a result, in one or more embodiments of this disclosure, it is not required to add a new photomask to fabricate the capacitor plate, thereby reducing the number of photomasks required in the display panel manufacturing process, lowering the process cost of the display panel, and shortening the process time of the display panel. Furthermore, the first sub-portion 511 and the second sub-portion 512 of the buffer layer 51 are respectively aligned with the active portion 31 and the functional electrode 32 of the semiconductor layer 30. Thus, in the manufacturing process, the same photomask can be used to pattern the buffer layer 51 and the semiconductor layer 30 to form the first sub-portion 511, the second sub-portion 512, the active portion 31, and the functional electrode 32. As a result, the number of photomasks required in the display panel manufacturing process can be further reduced, the process cost of the display panel can be further lowered, and the process time of the display panel can be further shortened.

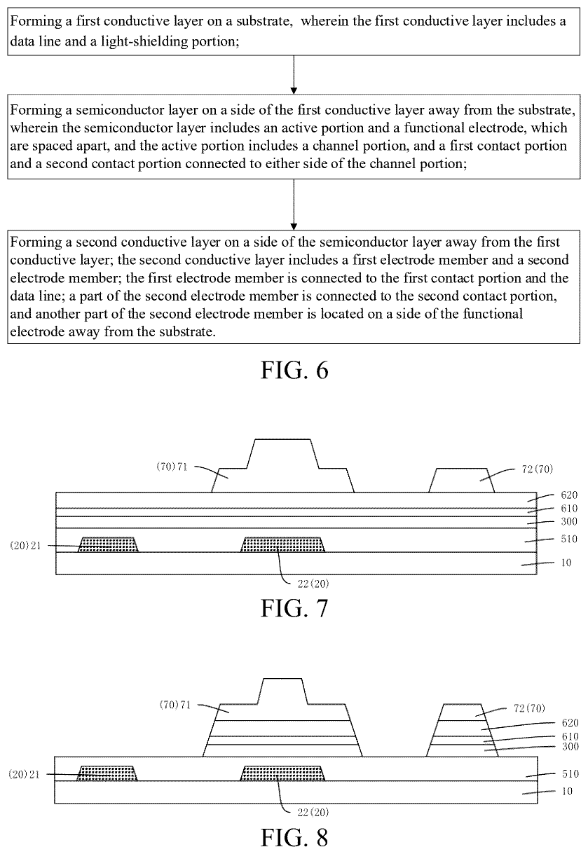

Additionally, one or more embodiments of this disclosure embodiment also provide a method for preparing the display panel as described in the aforementioned embodiments. Please refer to FIG. 2, FIG. 6, and FIGS. 7 to 12, the method for preparing the display panel includes:

Step S10, forming a first conductive layer 20 on a substrate 10, wherein the first conductive layer 20 includes a data line 21 and a light-shielding portion 22.

Step S20, forming a semiconductor layer 30 on a side of the first conductive layer 20 away from the substrate 10, wherein the semiconductor layer 30 includes an active portion 31 and a functional electrode 32, which are spaced apart, and the active portion 31 includes a channel portion 311, and a first contact portion 312 and a second contact portion 313 connected to either side of the channel portion 311.

Step S30, forming a second conductive layer 40 on a side of the semiconductor layer 30 away from the first conductive layer 20. The second conductive layer 40 includes a first electrode member 41 and a second electrode member 42. The first electrode member 41 is connected to the first contact portion 312 and the data line 21. One end of the second electrode member 42 is connected to the second contact portion 313, and the other end of the second electrode member 42 is located on a side of the functional electrode 32 away from the substrate 10.

Specifically, in step S10, the substrate 10 is provided, and the patterned first conductive layer 20 is formed on the substrate 10 by adopting a first photomask process. The first conductive layer 20 includes the data line 21 and the light-shielding portion 22.

Thereafter, a buffer material layer 510 is formed on the substrate 10, covering the data line 21 and the light-shielding portion 22. The buffer material layer 510 may include inorganic insulating materials, such as silicon nitride or silicon oxide.

In step S20, a semiconductor material layer 300, a gate insulating material layer 610, and a gate material layer 620 are formed on the buffer material layer 510 in sequence. Thereafter, a photoresist layer 70 is formed on the gate material layer 620 by adopting a second photomask process. The photoresist layer 70 can be formed through a semi-transparent mask. The photoresist layer 70 includes a first photoresist block 71 and a second photoresist block 72. The first photoresist block 71 is located on a side of the light-shielding portion 22 away from the substrate 10, with the middle portion of the first photoresist block 71 being relatively thicker while the peripheral portion of the first photoresist block 71 is relatively thinner. The second photoresist block 72 has a uniform thickness, which is equal to or similar to a thickness of the peripheral portion of the first photoresist block 71, as shown in FIG. 7.

As shown in FIG. 8, portions of the semiconductor material layer 300, the gate insulating material layer 610, and the gate material layer 620 that are not covered by the first photoresist block 71 and the second photoresist block 72 are removed.

Thereafter, a portion of the buffer material layer 510 that is not covered by the first photoresist block 71 and the second photoresist block 72 is removed to form a buffer layer 51. The buffer layer 51 includes a first sub-portion 511 and a second sub-portion 512, which are spaced apart.

Furthermore, it is necessary to remove the relatively thinner portion of the first photoresist block 71 and the entire second photoresist block 72, such that only the relatively thicker portion of the first photoresist block 71 remains.

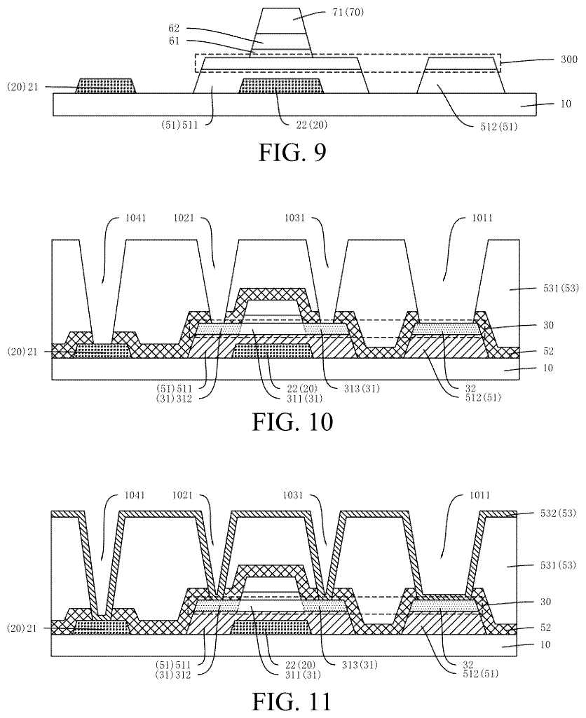

Thereafter, the gate insulating material layer 610 and the gate material layer 620 that are not covered by the remaining portion of the first photoresist block 71 are removed to form a gate insulating layer 61 located between the first photoresist block 71 and the semiconductor material layer 300, and a gate electrode 62 located between the gate insulating layer 61 and the first photoresist block 71, as shown in FIG. 9.

Additionally, the remaining portion of the first photoresist block 71 is removed. Then, portions of the semiconductor material layer 300, which are not covered by the gate insulating layer 61 and the gate 62, are treated by a conductorization process, to form the active portion 31 located between the gate insulating layer 61 and the first sub-portion 511, as well as the functional electrode 32 located on a side of the second sub-portion 512 away from the substrate 10. The active portion 31 includes the channel portion 311, the first contact portion 312, and the second contact portion 313, and the first contact portion 312 and the second contact portion 313 are connected to opposite sides of the channel portion 311. The first contact portion 312, the second contact portion 313, and the functional electrode 32 are all formed by treating the semiconductor material layer 300 using the conductorization process.

In some embodiments, the material of the semiconductor material layer 300 may include oxide semiconductor materials, specifically metal oxide semiconductor materials. For instance, the material of the semiconductor material layer 300 may include at least one of indium zinc oxides (IZO), gallium indium oxides (IGO), indium gallium zinc oxides (IGZO), indium gallium tin oxides (IGTO), and indium gallium zinc tin oxides (IGZTO).

Subsequently, a first insulating layer 52 is formed to cover the data line 21, the active portion 31, the gate electrode 62, and the functional electrode 32. Then, an organic insulating sublayer 531 is formed on a side of the first insulating layer 52 away from the substrate 10.

Thereafter, the organic insulating sublayer 531 and the first insulating layer 52 are patterned by adopting a third photomask process to form a first intermediate opening 1011 located on a side of the functional electrode 32 away from the substrate 10, a second intermediate opening 1021 located on a side of the first contact portion 312 away from the substrate 10, a third intermediate opening 1031 located on a side of the second contact portion 313 away from the substrate 10, and a fourth intermediate opening 1041 located on a side of the data line 21 away from the substrate 10, as shown in FIG. 10.

Furthermore, an inorganic insulating sublayer 532 is formed on a side of the organic insulating sublayer 531 away from the substrate 10. The inorganic insulating sublayer 532 covers a surface of the organic insulating sublayer 531 away from the substrate 10, sidewalls and bottom of the first intermediate opening 1011, sidewalls and bottom of the second intermediate opening 1021, sidewalls and bottom of the third intermediate opening 1031, and sidewalls and bottom of the fourth intermediate opening 1041, as shown in FIG. 11.

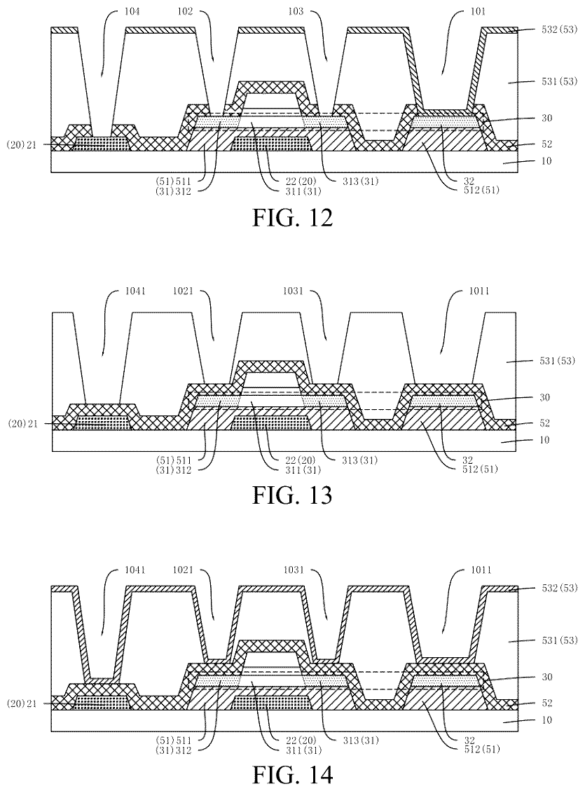

Subsequently, the inorganic insulating sublayer 532 is etched by adopting a fourth photomask process to remove the inorganic insulating sublayer 532 from the sidewalls and bottom of the second intermediate opening 1021, the sidewalls and bottom of the third intermediate opening 1031, and the sidewalls and bottom of the fourth intermediate opening 1041, with the sidewalls and bottom of the first intermediate opening 1011 being covered with the inorganic insulating sublayer 532, thereby forming a first opening 101 at a position of the first intermediate opening 1011, a second opening 102 at a position of the second intermediate opening 1021, a third opening 103 at a position of the third intermediate opening 1031, and a fourth opening 104 at a position of the fourth intermediate opening 1041, as shown in FIG. 12.

In step S30, a second conductive material layer is formed on the inorganic insulating sublayer 532, and the second conductive material layer is patterned by adopting a fifth photomask process, thereby forming the second conductive layer 40. The second conductive layer 40 includes the first electrode 41 and the second electrode 42.

One end of the first electrode member 41 extends through the second opening 102 to connect with the first contact portion 312, while the other end of the first electrode member 41 extends through the fourth opening 104 to connect with the data line 21. One end of the second electrode member 42 is connected to the second contact portion 313, and the other end of the second electrode member 42 is located on the side of the functional electrode 32 away from the substrate 10. Specifically, the second electrode member 42 includes a second sub-electrode 422 and a first sub-electrode 421, which connect with each other and are integrally formed.

One end of the second sub-electrode 422 is located on a surface of the inorganic insulating sublayer 532 away from the substrate 10, while the other end of the second sub-electrode 422 extends through the third opening 103 to connect with the second contact portion 313. The first sub-electrode 421 is located at the bottom of the first opening 101 and on the side of the functional electrode 32 away from the substrate 10. The inorganic insulating sublayer 532 is disposed between the first sub-electrode 421 and the functional electrode 32 to separate them, as shown in FIG. 2.

It should be noted that the display panel 100 may include a liquid crystal layer located on a side of the second conductive layer 40 away from the substrate 10, as well as an opposite substrate located on a side of the liquid crystal layer away from the second conductive layer 40. Additionally, a structure, like a color filter layer, can be arranged on the opposite substrate, which means the display panel 100 can be a liquid crystal display panel.

The second electrode member 42, which serves as a pixel electrode, is electrically connected to the active portion 31, the first electrode member 41, and the data line 21 to acquire a data signal from the data line 21.

The first sub-electrode 421 of the second electrode member 42 is positioned opposite to the functional electrode 32 to form a storage capacitor. An edge electric field is generated between the second sub-electrode 422 of the second electrode member 42 and the functional electrode 32, which can drive liquid crystal molecules in the liquid crystal layer to deflect, thereby enabling a display function of the display panel.

As mentioned above, the display panel 100 shown in FIG. 2 can be obtained by five photomask processes in one or more embodiments of this disclosure. Compared to the prior art shown in FIG. 1, this can reduce the number of photomasks required in a display panel manufacturing process, lower the process cost of the display panel, and shorten the process time of the display panel.

In another embodiment of this disclosure, please refer to FIG. 4, FIG. 6, FIG. 7 to FIG. 9, and FIG. 13 to FIG. 15, in step S10, the substrate 10 is provided, and the patterned first conductive layer 20 is formed on the substrate 10 by adopting a first photomask process. The first conductive layer 20 includes the data line 21 and the light-shielding portions 22.

Thereafter, a buffer material layer 510 is formed on the substrate 10, covering the data line 21 and the light-shielding portion 22. The buffer material layer 510 may include inorganic insulating materials, such as silicon nitride or silicon oxide.

In step S20, a semiconductor material layer 300, a gate insulating material layer 610, and a gate material layer 620 are formed on the buffer material layer 510 in sequence.

Thereafter, a photoresist layer 70 is formed on the gate material layer 620 by adopting a second photomask process. The photoresist layer 70 can be formed using a semi-transparent mask. The photoresist layer 70 includes a first photoresist block 71 and a second photoresist block 72. The first photoresist block 71 is located on a side of the light-shielding portion 22 away from the substrate 10, with the middle portion of the first photoresist block 71 being relatively thicker while the peripheral portion of the first photoresist block 71 is relatively thinner. The second photoresist block 72 has a uniform thickness, which is equal to or similar to a thickness of the peripheral portion of the first photoresist block 71, as shown in FIG. 7.

Portions of the semiconductor material layer 300, the gate insulating material layer 610, and the gate material layer 620 that are not covered by the first photoresist block 71 and the second photoresist block 72 are removed, as shown in FIG. 8.

Thereafter, a portion of the buffer material layer 510 that is not covered by the first photoresist block 71 and the second photoresist block 72 is removed to form a buffer layer 51. The buffer layer 51 includes a first sub-portion 511 and a second sub-portion 512, which are spaced apart.

Furthermore, it is necessary to remove the relatively thinner portion of the first photoresist block 71 and the entire second photoresist block 72, such that only the relatively thicker portion of the first photoresist block 71 remains.

Thereafter, the gate insulating material layer 610 and the gate material layer 620 that are not covered by the remaining portion of the first photoresist block 71 are removed to form a gate insulating layer 61 located between the first photoresist block 71 and the semiconductor material layer 300, and a gate electrode 62 located between the gate insulating layer 61 and the first photoresist block 71, as shown in FIG. 9.

Additionally, the remaining portion of the first photoresist block 71 is removed, and then, portions of the semiconductor material layer 300 that are not covered by the gate insulating layer 61 and gate 62 are treated by a conductorization process, to form the active portion 31 located between the gate insulating layer 61 and the first sub-portion 511, as well as the functional electrode 32 located on a side of the second sub-portion 512 away from the substrate 10. The active portion 31 includes the channel portion 311, as well as the first contact portion 312 and the second contact portion 313, which are connected to opposite sides of the channel portion 311. The first contact portion 312, the second contact portion 313, and the functional electrode 32 are all formed by treating the semiconductor material layer 300 using the conductorization process.

In some embodiments, the material of the semiconductor material layer 300 may include oxide semiconductor materials, specifically metal oxide semiconductor materials. For example, the material of the semiconductor material layer 300 may include at least one of indium zinc oxides (IZO), gallium indium oxides (IGO), indium gallium zinc oxides (IGZO), indium gallium tin oxides (IGTO), and indium gallium zinc tin oxides (IGZTO).

Subsequently, a first insulating layer 52 is formed to cover the data line 21, the active portion 31, the gate electrode 62, and the functional electrode 32. Then, an organic insulating sublayer 531 is formed on a side of the first insulating layer 52 away from the substrate 10.

Thereafter, the organic insulating sublayer 531 is patterned by adopting a third photomask process to form a first intermediate opening 1011 located on a side of the functional electrode 32 away from the substrate 10, a second intermediate opening 1021 located on a side of the first contact portion 312 away from the substrate 10, a third intermediate opening 1031 located on a side of the second contact portion 313 away from the substrate 10, and the fourth intermediate opening 1041 located on a side of the data line 21 away from the substrate 10, as shown in FIG. 13.

Furthermore, an inorganic insulating sublayer 532 is formed on a side of the organic insulating sublayer 531 away from the substrate 10; and the inorganic insulating sublayer 532 covers a surface of the organic insulating sublayer 531 away from the substrate 10, sidewalls and bottom of the first intermediate opening 1011, sidewalls and bottom of the second intermediate opening 1021, sidewalls and bottom of the third intermediate opening 1031, and sidewalls and bottom of the fourth intermediate opening 1041, as shown in FIG. 14.

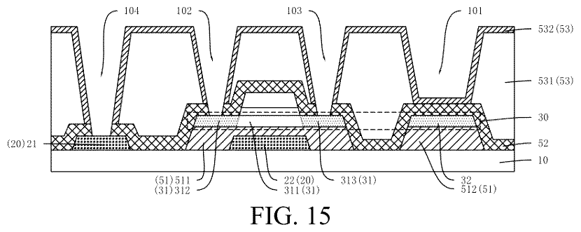

Subsequently, the inorganic insulating sublayer 532 and the first insulating layer 52 are etched by adopting a fourth photomask process to remove the inorganic insulating sublayer 532 and the first insulating layer 52 from the bottom of the second intermediate opening 1021, the bottom of the third intermediate opening 1031, and the bottom of the fourth intermediate opening 1041, with the sidewalls and bottom of the first intermediate opening 1011 being covered with the inorganic insulating sublayer 532 and the first insulating layer 52, thereby forming a first opening 101 at a position of the first intermediate opening 1011, a second opening 102 at a position of the second intermediate opening 1021, a third opening 103 at a position of the third intermediate opening 1031, and a fourth opening 104 at a position of the fourth intermediate opening 1041, as shown in FIG. 15.

In step S30, a second conductive material layer is formed on the inorganic insulating sublayer 532, and the second conductive material layer is patterned by adopting a fifth photomask process to form the second conductive layer 40, which includes the first electrode member 41 and the second electrode member 42.

One end of the first electrode member 41 extends through the second opening 102 to connect with the first contact portion 312, while the other end of the first electrode member 41 extends through the fourth opening 104 to connect with the data line 21. One end of the second electrode member 42 is connected to the second contact portion 313, and the other end of the second electrode member 42 is located on the side of the functional electrode 32 away from the substrate 10. Specifically, the second electrode member 42 includes a second sub-electrode 422 and a first sub-electrode 421, which connect with each other and are integrally formed.

One end of the second sub-electrode 422 is located on a surface of the inorganic insulating sublayer 532 away from the substrate 10, while the other end of the second sub-electrode 422 extends through the third opening 103 to connect with the second contact portion 313. The first sub-electrode 421 is located at the bottom of the first opening 101 and on the side of the functional electrode 32 away from the substrate 10. The inorganic insulating sublayer 532 and the first insulating layer 52 are disposed between the first sub-electrode 421 and the functional electrode 32 to separate them, as shown in FIG. 4.

It should be understood that the display panel 100 may include a liquid crystal layer located on a side of the second conductive layer 40 away from the substrate 10, as well as an opposite substrate located on a side of the liquid crystal layer away from the second conductive layer 40. Additionally, a structure, like a color filter layer, can be arranged on the opposite substrate, which means the display panel 100 can be a liquid crystal display panel.

The second electrode member 42, which serves as a pixel electrode, is electrically connected to the active portion 31, the first electrode member 41, and the data line 21 to acquire a data signal from the data line 21.

The first sub-electrode 421 of the second electrode member 42 is positioned opposite to the functional electrode 32 to form a storage capacitor. An edge electric field is generated between the second sub-electrode 422 of the second electrode member 42 and the functional electrode 32, which can drive liquid crystal molecules in the liquid crystal layer to deflect, thereby enabling a display function of the display panel.

As mentioned above, the display panel 100 shown in FIG. 4 can be obtained through five photomask processes in one or more embodiments of this disclosure. Compared to the prior art shown in FIG. 1, this can reduce the number of photomasks required in a display panel manufacturing process, lower the process cost of the display panel, and shorten the process time of the display panel.

Furthermore, compared to the embodiments illustrated in FIG. 2 and FIG. 4, in other embodiments of this disclosure, the second insulating layer 53 includes either an organic insulating sublayer 531 located between the first insulating layer 52 and the second conductive layer 40, or an inorganic insulating sublayer 532 located between the first insulating layer 52 and the second conductive layer 40, which allows the display panel 100 to be obtained by adopting four photomask processes, and thus the number of photomasks can be further reduced.

Additionally, one or more embodiments of this disclosure further provide a display device. The display device includes the display panel 100 described in the aforementioned embodiments, or the display panel produced by the method for preparing the display panel detailed in the aforementioned embodiments.

In some embodiments, the display device may be a Liquid Crystal Display (LCD) or an Organic Light-Emitting Diode (OLED) display.

Since the display device includes the display panel 100 described in the above embodiments, it can be understood that the display device will have the same beneficial effects as the display panel. Therefore, details are not described herein again.

In the description of this disclosure, the terms “first”, “second”, etc. are only used for descriptive purposes, and cannot be understood as indicating or implying relative importance or implicitly indicating the number of technical features indicated. Thus, the characteristics that are defined as “first” or “second”, etc. may explicitly or implicitly include one or more of the characteristics. In the description of this disclosure, “multiple” means two or more, unless otherwise specifically limited.

In the aforementioned embodiments, the descriptions of each embodiment have their own emphases, and for parts not described in detail in a certain embodiment, please refer to the relevant descriptions in other embodiments.

The embodiments, implementations, and related technical characteristics described in this disclosure can be combined or interchanged with each other as long as there is no conflict.

The embodiments mentioned above are merely part of the embodiments of this disclosure and should not be construed as limiting the disclosure in any form. Any simple modifications, equivalent variations, or embellishments made to the above embodiments based on the technical essence of this disclosure, without departing from the content of the technical solutions of this disclosure, shall fall within the scope of this disclosure.

What is claimed is:

1. A display panel comprising:
a substrate;
a first conductive layer disposed on the substrate and comprising a data line and a light-shielding portion;
a semiconductor layer disposed on a side of the first conductive layer away from the substrate and comprising an active portion and a functional electrode spaced apart from each other, wherein the active portion comprises a channel portion as well as a first contact portion and a second contact portion connected to either side of the channel portion; and
a second conductive layer disposed on a side of the semiconductor layer away from the first conductive layer,
wherein the second conductive layer comprises a first electrode member and a second electrode member, the first electrode member is connected to the first contact portion and the data line, a part of the second electrode member is connected to the second contact portion, and another part of the second electrode member is located on a side of the functional electrode away from the substrate.

2. The display panel of claim 1, wherein the display panel further comprises:
a buffer layer disposed between the first conductive layer and the semiconductor layer;
a first insulating layer disposed between the semiconductor layer and the second conductive layer; and
a second insulating layer disposed between the first insulating layer and the second conductive layer;
wherein the display panel has a first opening corresponding to the functional electrode, the first opening penetrates through a part of film layers of the first insulating layer and the second insulating layer, the second electrode member comprises a first sub-electrode located at the bottom of the first opening, and the first sub-electrode is located on the side of the functional electrode away from the substrate and spaced apart from the functional electrode.

3. The display panel of claim 2, wherein the second insulating layer comprises an organic insulating sublayer positioned between the first insulating layer and the second conductive layer, and an inorganic insulating sublayer positioned between the organic insulating sublayer and the second conductive layer.

4. The display panel of claim 3, wherein the first opening penetrates through the organic insulating sublayer, with sidewalls of the first opening being surfaces of the inorganic insulating sublayer, and the first insulating layer and the inorganic insulating sublayer are disposed between the first sub-electrode and the functional electrode to separate the first sub-electrode and the functional electrode.

5. The display panel of claim 3, wherein the first opening penetrates through the organic insulating sublayer and the first insulating layer, with sidewalls of the first opening being surfaces of the inorganic insulating sublayer, and the inorganic insulating sublayer is disposed between the first sub-electrode and the functional electrode to separate the first sub-electrode and the functional electrode.

6. The display panel of claim 2, wherein the second insulating layer comprises an organic insulating sublayer located between the first insulating layer and the second conductive layer; or
the second insulating layer comprises an inorganic insulating sublayer located between the first insulating layer and the second conductive layer.

7. The display panel of claim 2, wherein the display panel further comprises a second opening and a third opening, the second opening penetrates through the second insulating layer and the first insulating layer, and corresponds to the first contact portion, the third opening penetrates through the second insulating layer and the first insulating layer and corresponds to the second contact portion, the first electrode member extends through the second opening to connect with the first contact portion, the second electrode member further comprises a second sub-electrode connected to the first sub-electrode, one end of the second sub-electrode is located on a side of the second insulating layer away from the first insulating layer, and the other end of the second sub-electrode extends through the third opening to connect with the second contact portion.

8. The display panel of claim 7, wherein the display panel further comprises a fourth opening that penetrates through the second insulating layer and the first insulating layer and corresponds to the data line, and the first electrode member extends through the fourth opening to connect with the data line.

9. The display panel of claim 8, wherein a depth of the fourth opening is greater than a depth of the second opening, and the depth of the fourth opening is greater than a depth of the third opening.

10. The display panel of claim 8, wherein the first electrode member covers sidewalls of the second and fourth openings, part of a surface of the data line away from the substrate, and at least part of a surface of the first contact portion away from the substrate, and the second sub-electrode covers sidewalls of the third opening and at least part of a surface of the second contact portion away from the substrate.

11. The display panel of claim 2, wherein the buffer layer comprises a first sub-portion and a second sub-portion that are spaced apart from each other, with the first sub-portion being located between the active portion and the substrate, and the second sub-portion being located between the functional electrode and the substrate.

12. The display panel of claim 1, wherein an orthographic projection of the buffer layer on the substrate overlaps with an orthographic projection of the semiconductor layer on the substrate.

13. The display panel of claim 1, wherein the display panel further comprises a liquid crystal layer located on a side of the second conductive layer away from the substrate, and an opposite substrate located on a side of the liquid crystal layer away from the second conductive layer, wherein the second electrode member is a pixel electrode; or
the display panel further comprises a light-emitting functional layer disposed on the side of the second conductive layer away from the substrate, and a cathode layer disposed on a side of the light-emitting functional layer away from the second conductive layer, wherein the second electrode member is an anode.

14. The display panel of claim 1, wherein the semiconductor layer comprises oxide semiconductor materials.

15. A method for preparing a display panel, comprising:
forming a first conductive layer on a substrate, with the first conductive layer comprising a data line and a light-shielding portion;
forming a semiconductor layer on a side of the first conductive layer away from the substrate, with the semiconductor layer comprising an active portion and a functional electrode spaced apart from each other, wherein the active portion comprises a channel portion, a first contact portion and a second contact portion, wherein the first contact portion and the second contact portion are connected to either side of the channel portion; and
forming a second conductive layer on a side of the semiconductor layer away from the first conductive layer, wherein the second conductive layer comprises a first electrode member and a second electrode member, the first electrode member is connected to the first contact portion and the data line, a part of the second electrode member is connected to the second contact portion, and another part of the second electrode member is located on a side of the functional electrode away from the substrate.

16. A display device comprising:
a display panel;
wherein the display panel comprises:
a substrate;
a first conductive layer disposed on the substrate and comprising a data line and a light-shielding portion;
a semiconductor layer disposed on a side of the first conductive layer away from the substrate and comprising an active portion and a functional electrode spaced apart from each other, wherein the active portion comprises a channel portion as well as a first contact portion and a second contact portion connected to either side of the channel portion; and
a second conductive layer disposed on a side of the semiconductor layer away from the first conductive layer,
wherein the second conductive layer comprises a first electrode member and a second electrode member, the first electrode member is connected to the first contact portion and the data line, a part of the second electrode member is connected to the second contact portion, and another part of the second electrode member is located on a side of the functional electrode away from the substrate.

17. The display device of claim 16, wherein the display panel further comprises:
a buffer layer disposed between the first conductive layer and the semiconductor layer;
a first insulating layer disposed between the semiconductor layer and the second conductive layer; and
a second insulating layer disposed between the first insulating layer and the second conductive layer;
wherein the display panel has a first opening corresponding to the functional electrode, the first opening penetrates through a part of film layers of the first insulating layer and the second insulating layer, the second electrode member comprises a first sub-electrode located at the bottom of the first opening, and the first sub-electrode is located on the side of the functional electrode away from the substrate and is spaced apart from the functional electrode.

18. The display device of claim 17, wherein the second insulating layer comprises an organic insulating sublayer located between the first insulating layer and the second conductive layer; or
the second insulating layer comprises an inorganic insulating sublayer located between the first insulating layer and the second conductive layer.

19. The display device of claim 17, wherein the display panel further comprises a second opening and a third opening, the second opening penetrates through the second insulating layer and the first insulating layer and corresponds to the first contact portion, and the third opening penetrates through the second insulating layer and the first insulating layer and corresponds to the second contact portion, wherein the first electrode member extends through the second opening to connect with the first contact portion, the second electrode member further comprises a second sub-electrode connected to the first sub-electrode, one end of the second sub-electrode is located on a side of the second insulating layer away from the first insulating layer, and the other end of the second sub-electrode extends through the third opening to connect with the second contact portion.

20. The display device of claim 16, wherein the display panel further comprises a liquid crystal layer located on a side of the second conductive layer away from the substrate, and an opposite substrate located on a side of the liquid crystal layer from the second conductive layer, wherein the second electrode member is a pixel electrode; or
the display panel further comprises a light-emitting functional layer disposed on the side of the second conductive layer away from the substrate, and a cathode layer disposed on a side of the light-emitting functional layer away from the second conductive layer, wherein the second electrode member is an anode.
